(19) United States
(12) Patent Application Publication
(10) Pub. No.: US 2025/0294650 A1
(43) Pub. Date: Sep. 18, 2025

(54) HEAT TREATMENT APPARATUS AND HEAT TREATMENT METHOD FOR HEATING SUBSTRATE BY FLASH IRRADIATION

(71) Applicant: SCREEN Holdings Co., Ltd., Kyoto (JP)

(72) Inventors: Shinji MIYAWAKI, Kyoto-shi (JP); Hiroyasu TAKEHARA, Kyoto-shi (JP); Jumpei NIKI, Kyoto-shi (JP); Kazunori AMAGO, Tokyo (JP)

(21) Appl. No.: 19/015,620

(22) Filed: Jan. 9, 2025

(30) Foreign Application Priority Data
Mar. 13, 2024 (JP) 2024-038556

(51) Int. Cl. H05B 7/16; H05B 7/18

(52) U.S. Cl. CPC H05B 7/16; H05B 7/185

(57) ABSTRACT

A semiconductor wafer received in a chamber is preheated by light irradiation from halogen lamps, and is thereafter irradiated with flashes of light from flash lamps. Prior to the flash irradiation, ozone is stored in a gas storage tank, so that the pressure in the gas storage tank is higher than atmospheric pressure. On the other hand, the pressure in the chamber is reduced to lower than atmospheric pressure. In this condition, a supply valve is opened between the time when the flash lamps turn on to start the flash irradiation and the time when the temperature of a front surface of the semiconductor wafer reaches a peak temperature. This allows ozone gas to flow all at once from the gas storage tank toward the chamber, thereby supplying the ozone gas instantaneously into the chamber.

### BACKGROUND OF THE INVENTION

### Field of the Invention

The present invention relates to a heat treatment apparatus and a heat treatment method which irradiate a substrate with a flash of light to heat the substrate. Examples of the substrate to be treated include a semiconductor wafer, a substrate for a liquid crystal display device, a substrate for a flat panel display (FPD), a substrate for an optical disk, a substrate for a magnetic disk, and a substrate for a solar cell.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

An attempt has been made to apply the flash lamp annealing to the formation of oxide films (as disclosed in U.S. Patent Application Publication No. 2020/0286756). The flash lamp annealing, which is capable of heating the surface of the semiconductor wafer to a high temperature in an extremely short time, is suitable for the formation of thin oxide films having good properties. For purposes of preventing the formation of low-quality oxide films at low temperatures, the technique disclosed in U.S. Patent Application Publication No. 2020/0286756 performs heating in a nitrogen atmosphere in the initial stage thereof, and supplies an oxidizing gas such as oxygen to change the atmosphere in a chamber from the nitrogen atmosphere to an oxidizing atmosphere when the semiconductor wafer is heated to a certain temperature.

In recent years, demands for the thickness and quality of oxide films have become increasingly strict, and oxidation only in a higher temperature range has been required. Specifically, it has been considered ideal to cause an oxidation reaction only in a peak temperature range during flash irradiation. To this end, it has been necessary to supply the oxidizing gas instantaneously and in large quantities during the flash irradiation. However, conventional gas control techniques have not been able to achieve such gas supply.

### SUMMARY

The present invention is intended for a heat treatment apparatus for heating a substrate by irradiating the substrate with a flash of light.

According to one aspect of the present invention, the heat treatment apparatus

comprises: a chamber for receiving a substrate therein; a flash lamp for irradiating a front surface of the substrate received in the chamber with a flash of light to increase the temperature of the front surface of the substrate to a predetermined treatment temperature; a gas supply part for supplying a treatment gas into the chamber; an exhaust part for exhausting gas from the chamber to reduce the pressure in the chamber; and a controller for controlling the gas supply part and the exhaust part, wherein the gas supply part includes a gas storage part for storing the treatment gas, and a supply valve provided in a pipe for connecting the gas storage part and the chamber to each other for communication therebetween, and wherein the controller controls the gas supply part so that the supply valve is opened at a predetermined timing in such a condition that the pressure in the gas storage part is higher than atmospheric pressure and the pressure in the chamber is reduced to lower than atmospheric pressure.

This allows the treatment gas to flow all at once from the gas storage part which is pressurized toward the chamber which is depressurized, thereby supplying the treatment gas instantaneously into the chamber.

Preferably, the controller controls the gas supply part so that the supply valve is opened between the time when the flash lamp turns on to start flash irradiation and the time when the temperature of the front surface of the substrate reaches the treatment temperature.

The treatment gas is supplied at the instant when the front surface temperature of the substrate reaches the treatment temperature.

The present invention is also intended for a method of heating a substrate by irradiating the substrate with a flash of light.

According to one aspect of the present invention, the method comprises the steps of: (a) receiving a substrate in a chamber; (b) irradiating a front surface of the substrate received in the chamber with a flash of light from a flash lamp to increase the temperature of the front surface of the substrate to a predetermined treatment temperature; (c) exhausting gas from the chamber to reduce the pressure in the chamber to lower than atmospheric pressure; and (d) storing a treatment gas in a gas storage part to make the pressure in the gas storage part higher than atmospheric pressure, wherein a supply valve provided in a pipe for connecting the gas storage part and the chamber to each other for communication therebetween is opened at a predetermined timing in such a condition that the pressure in the gas storage part is higher than atmospheric pressure and the pressure in the chamber is reduced to lower than atmospheric pressure.

This allows the treatment gas to flow all at once from the gas storage part which is pressurized toward the chamber which is depressurized, thereby supplying the treatment gas instantaneously into the chamber.

Preferably, the supply valve is opened between the time when the flash lamp turns on to start flash irradiation and the time when the temperature of the front surface of the substrate reaches the treatment temperature.

The treatment gas is supplied at the instant when the front surface temperature of

the substrate reaches the treatment temperature.

It is therefore an object of the present invention to supply a treatment gas instantaneously into a chamber.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a view schematically showing a supply and exhaust mechanism for a chamber;

FIG. 9 is a flow diagram showing a procedure for treatment of a semiconductor wafer in the heat treatment apparatus of FIG. 1;

FIG. 10 is a graph showing transitions of the pressure in the chamber and the front surface temperature of the semiconductor wafer;

FIG. 11 is a graph showing changes in the front surface temperature of the semiconductor wafer before and after flash irradiation; and

FIG. 12 is a view schematically showing a phenomenon occurring in the chamber at the instant of opening a supply valve.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

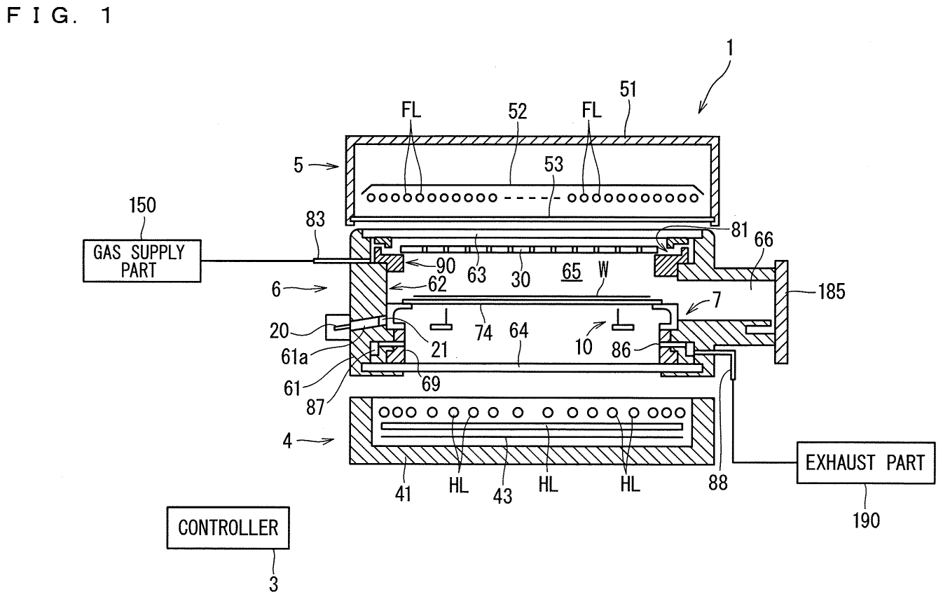

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. The heat treatment apparatus 1 further includes a holder 7 provided inside the chamber 6 and for holding a semiconductor wafer W in a horizontal attitude, a transfer mechanism 10 provided inside the chamber 6 and for transferring a semiconductor wafer W between the holder 7 and the outside of the heat treatment apparatus 1, and a shower plate 30 provided inside the chamber 6. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

A gas ring 90 is mounted to an upper portion of the inner wall surface of the chamber side portion 61, and a reflective ring 69 is mounted to a lower portion thereof. Both the gas ring 90 and the reflective ring 69 are in the form of an annular ring. An interior space of the chamber 6, i.e. a space surrounded by the upper chamber window 63, the lower chamber window 64, the chamber side portion 61, the reflective ring 69, and the gas ring 90 is defined as a heat treatment space 65.

A recessed portion 62 is defined in the inner wall surface of the chamber 6 by mounting the reflective ring 69 and the gas ring 90 to the chamber side portion 61. Specifically, the recessed portion 62 is defined which is surrounded by a middle portion of the inner wall surface of the chamber side portion 61 where the reflective ring 69 and the gas ring 90 are not mounted, an upper end surface of the reflective ring 69, and a lower end surface of the gas ring 90. The recessed portion 62 is provided in the form of a horizontal annular ring in the inner wall surface of the chamber 6, and surrounds the holder 7 which holds a semiconductor wafer W.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. A transparent window 21 made of barium fluoride material or calcium fluoride material transparent to infrared light in a wavelength range measurable by the radiation thermometer 20 is mounted to an end portion of the through hole 61a which faces the heat treatment space 65.

At least one gas supply opening 81 for supplying a treatment gas therethrough into the heat treatment space 65 is provided in the gas ring 90 mounted to an upper portion of the inner wall of the chamber 6. The gas supply opening 81 is connected in communication with a gas supply pipe 83 through a flow passage formed inside the gas ring 90. The gas supply pipe 83 is connected to a gas supply part 150. At least one gas exhaust opening 86 for exhausting a gas from the heat treatment space 65 is provided in a lower portion of the inner wall of the chamber 6. The gas exhaust opening 86 is provided below the recessed portion 62, and may be provided in the reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. In the present preferred embodiment, gas is supplied from above the semiconductor wafer W held by the holder 7 within the chamber 6, and is exhausted from below the semiconductor wafer W. Details on a supply and exhaust mechanism for the chamber 6 will be described later.

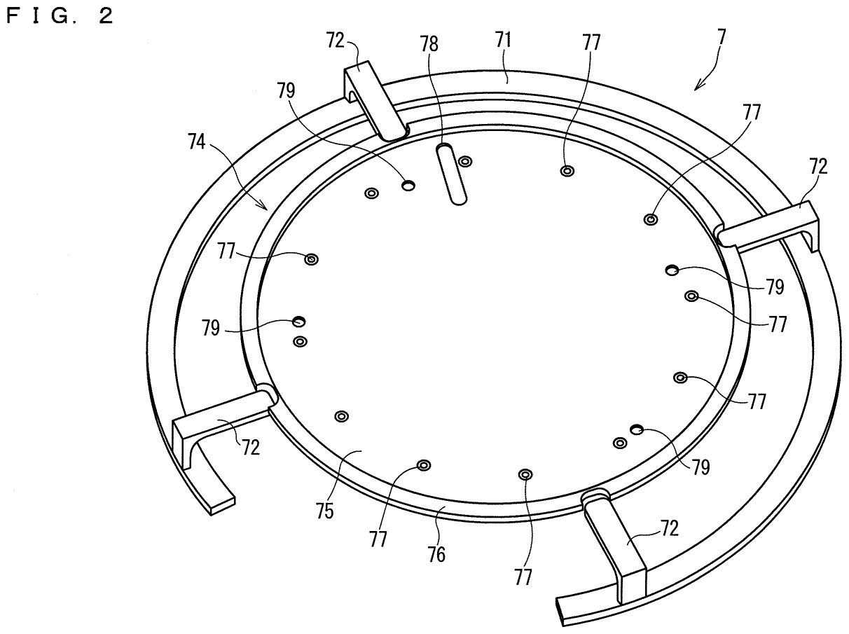

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

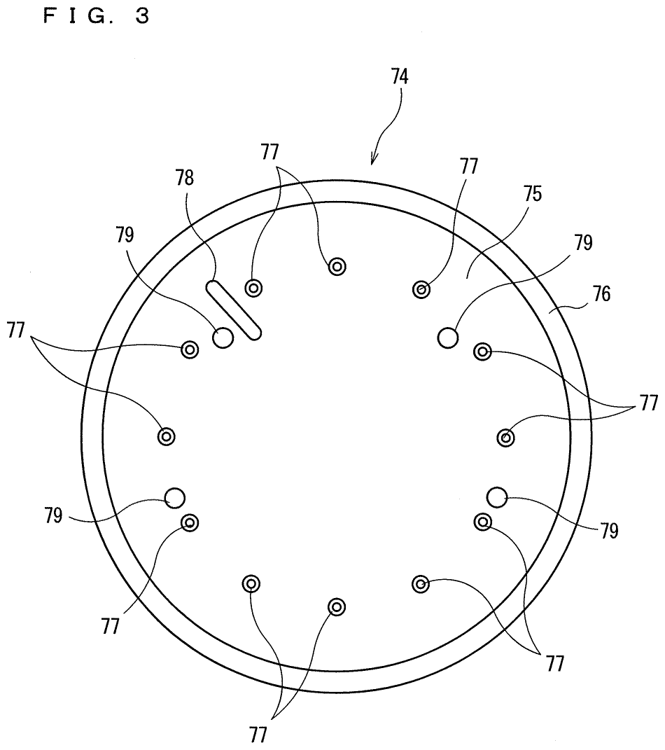

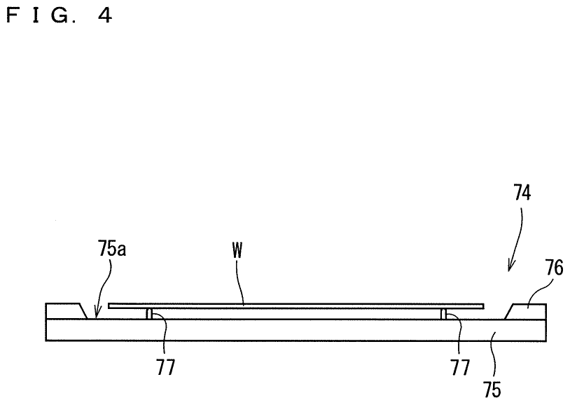

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 200 to 280 mm when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the radiation thermometer 20 to receive radiation (infrared light) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

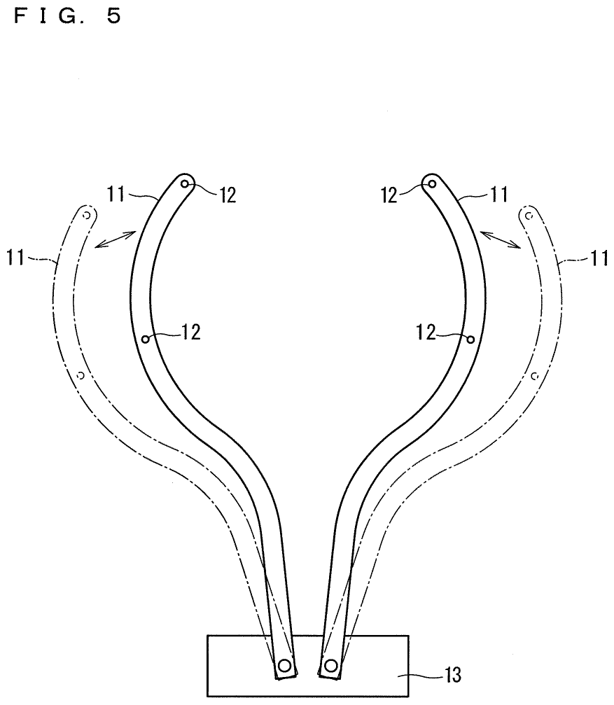

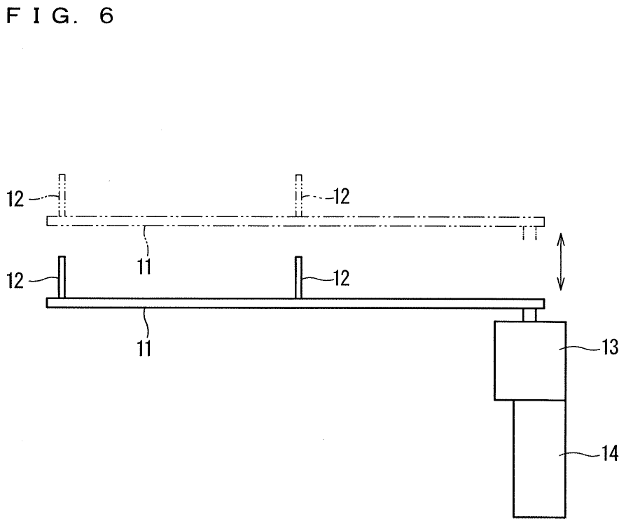

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

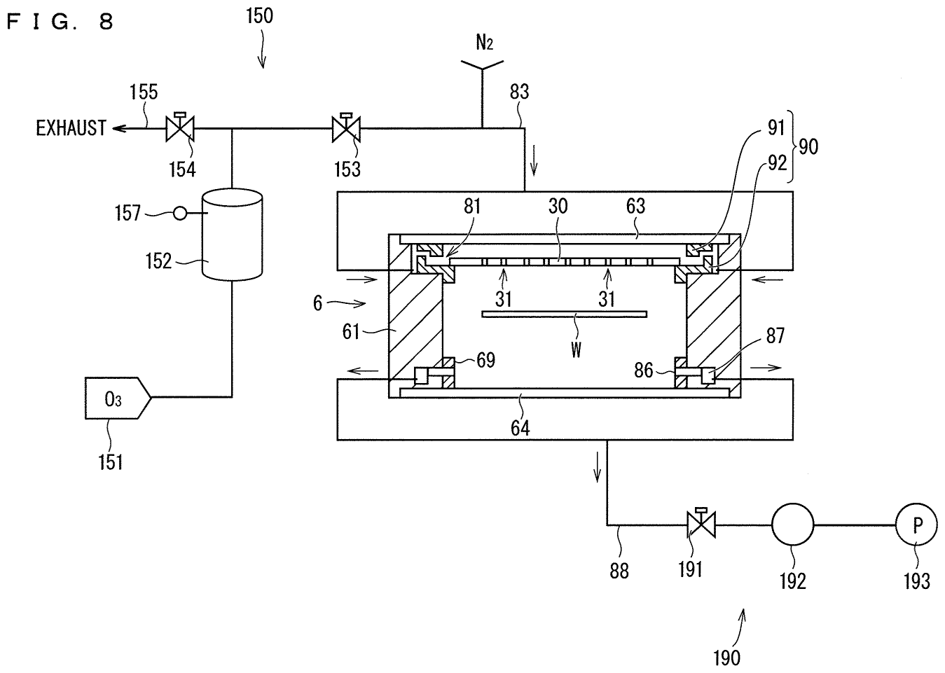

FIG. 8 is a view schematically showing the supply and exhaust mechanism for the

chamber 6. The gas ring 90 and the shower plate 30 are provided in an upper portion of the chamber 6. The gas ring 90 mounted to the upper portion of the inner wall surface of the chamber side portion 61 having the generally tubular shape has an annular shape. The gas ring 90 is mounted so that the center thereof coincides with the center of the chamber side portion 61. In other words, the radial and circumferential directions of the gas ring 90 coincide with those of the chamber side portion 61. The gas ring 90 includes an upper ring 91 and a lower ring 92. Both the upper ring 91 and the lower ring 92 have an annular shape. The upper ring 91 and the lower ring 92 are stacked together to form the gas ring 90.

In a structure in which the upper and lower rings 91 and 92 having the annular shape are stacked together, a gap is formed between the upper ring 91 and the lower ring 92 to serve as the flow passage in the gas ring 90. This flow passage may have buffer, labyrinth, and other structures that are able to act as a resistance to the flow of gas. One end portion of the flow passage which faces the inside of the chamber 6 is the gas supply opening 81. The other end portion of the flow passage is connected to the gas supply pipe 83. The gas supply pipe 83 is connected to the gas supply part 150.

The shower plate 30 is a disk-shaped member made of quartz. Like the upper chamber window 63, the shower plate 30 thus allows flashes of light emitted from the flash heating part 5 to pass therethrough. The shower plate 30 is provided with a plurality of ejection holes 31 bored therein and extending vertically therethrough. The size of a region in which the ejection holes 31 are disposed is, for example, approximately the same as the size of the semiconductor wafer W as seen in plan view. Each of the ejection holes 31 has a diameter of approximately several millimeters. The ejection holes 31 need not have a uniform diameter. For example, the ejection holes 31 may have diameters gradually decreasing from the center of the shower plate 30 toward a peripheral portion thereof.

As shown in FIG. 8, the disk-shaped shower plate 30 is mounted in the chamber 6, with the peripheral portion thereof supported by the lower ring 92 of the gas ring 90. Thus, the shower plate 30 is provided above the holder 7. When the shower plate 30 is mounted in the chamber 6, a space is formed between the upper chamber window 63 and the shower plate 30.

A treatment gas fed from the gas supply part 150 through the gas supply pipe 83 to the gas ring 90 passes through the flow passage in the gas ring 90, and is supplied through the gas supply opening 81 into the space formed between the upper chamber window 63 and the shower plate 30. The treatment gas is ejected downwardly from the ejection holes 31 provided in the shower plate 30. The treatment gas ejected in a shower-like manner from the shower plate 30 forms a downflow of treatment gas directed downwardly from above in the heat treatment space 65.

The gas supply part 150 includes an ozone generator 151, a gas storage tank 152, a supply valve 153, and an exhaust valve 154. The ozone generator 151 generates ozone (O₃) by irradiating oxygen (O₂) with ultraviolet light or discharging in oxygen, for example. The ozone generator 151 sends the generated ozone to the gas storage tank 152. The gas storage tank 152 is a buffer tank for temporarily storing the ozone fed from the ozone generator 151. When the chamber 6 has an internal volume of 25 liters, the gas storage tank 152 has a volume of 1 to 2 liters, for example. The gas storage tank 152 is provided with a pressure sensor 157. The pressure sensor 157 measures the pressure of ozone stored in the gas storage tank 152.

The gas supply pipe 83 is a pipe for connecting the gas storage tank 152 and the gas ring 90 of the chamber 6 to each other for communication therebetween. The supply valve 153 is provided in the gas supply pipe 83. When the supply valve 153 is opened, the ozone gas stored in the gas storage tank 152 is supplied to the chamber 6.

An exhaust pipe 155 branches off from a mid-portion of the gas supply pipe 83 which is between the gas storage tank 152 and the supply valve 153, and is connected thereto. The exhaust valve 154 is provided in the exhaust pipe 155. When the exhaust valve 154 is opened, the ozone gas stored in the gas storage tank 152 is exhausted to the outside of the heat treatment apparatus 1. Valves having a fast response speed are preferably used as the supply valve 153 and the exhaust valve 154, and electromagnetic valves, for example, may be used.

A nitrogen (N₂) supply line is connected to a mid-portion of the gas supply pipe 83 which is between the supply valve 153 and the gas ring 90. Nitrogen gas fed through this supply line flows in the gas supply pipe 83 and is supplied to the chamber 6.

The supply valve 153 and the exhaust valve 154 are opened alternatively. Specifically, when the supply valve 153 is open, the exhaust valve 154 is closed. Conversely, when the exhaust valve 154 is open, the supply valve 153 is closed.

The gas exhaust pipe 88 is connected to the exhaust part 190. The exhaust part 190 includes a main valve 191, an automatic pressure control valve (APC or Automatic Pressure Controller) 192, and a vacuum pump 193. When the main valve 191 is opened while the vacuum pump 193 is operating, the gas in the chamber 6 is exhausted through the gas exhaust pipe 88. When the flow rate of the gas exhausted from the chamber 6 by the exhaust part 190 is higher than the flow rate of the gas supplied through the gas ring 90 into the chamber 6, the pressure in the chamber 6 is reduced to less than atmospheric pressure. The automatic pressure control valve 192 eliminates pressure variations, if any, during the reduction in pressure in the chamber 6 to maintain a constant pressure in the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 directs light from under the chamber 6 through the lower chamber window 64 toward the heat treatment space 65 to heat the semiconductor wafer W by means of the halogen lamps HL.

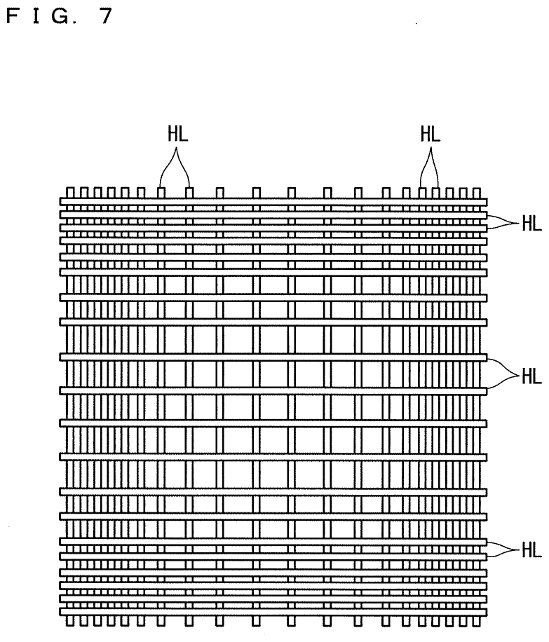

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape. The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to a peripheral portion of the semiconductor wafer W held by the holder 7 than in a region opposed to a central portion thereof. In other words, the halogen lamps HL in each of the upper and lower tiers are arranged at shorter intervals in a peripheral portion of the lamp arrangement than in a central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed. The controller 3 controls the gas supply part 150 and the exhaust part 190, and more specifically controls the opening and closing of the supply valve 153, the exhaust valve 154, and the main valve 191.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

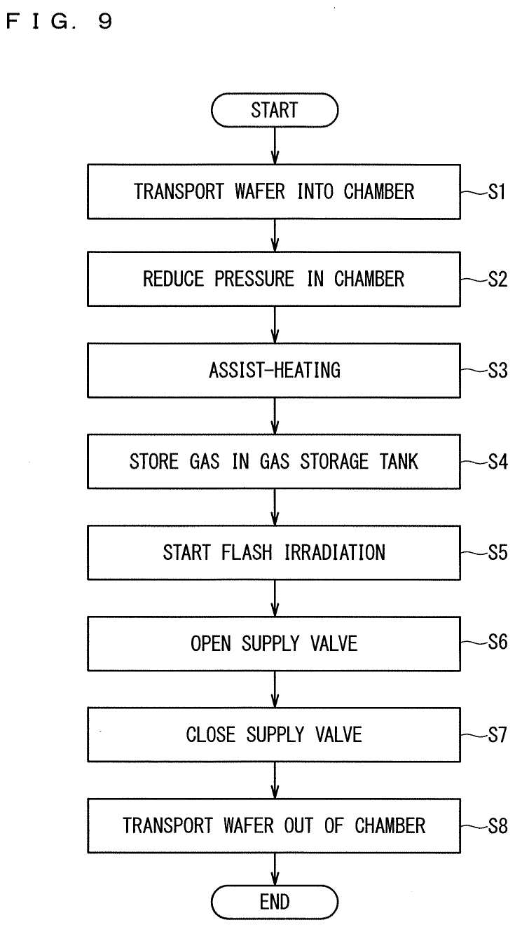

Next, a procedure for the treatment of a semiconductor wafer W in the heat treatment apparatus 1 will be described. FIG. 9 is a flow diagram showing the procedure for the treatment of the semiconductor wafer W. A substrate to be treated in the present preferred embodiment is a silicon (Si) semiconductor wafer W. Silicon that is a base material is exposed in at least part of a front surface of the semiconductor wafer W. Prior to a heat treatment method according to the present invention, a cleaning process using hydrofluoric acid and the like may be performed on the front surface of the semiconductor wafer W to remove a native oxide film formed in a location where silicon is exposed.

First, the silicon semiconductor wafer W is transported into the chamber 6 of the heat treatment apparatus 1 (Step S1). Specifically, the gate valve 185 is opened to open the transport opening 66. A transport robot outside the heat treatment apparatus 1 transports the semiconductor wafer W through the transport opening 66 into the heat treatment space 65 of the chamber 6. At this time, nitrogen gas may be supplied through the gas ring 90 into the chamber 6 and caused to flow outwardly through the transport opening 66, thereby minimizing an outside atmosphere carried into the heat treatment space 65 as the semiconductor wafer W is transported into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot

moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof where silicon is exposed partially is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the gate valve 185 closes the transport opening 66 so that the heat treatment space 65 becomes an enclosed space, the gas in the chamber 6 is exhausted while nitrogen is supplied into the chamber 6, so that the pressure in the chamber 6 is reduced (Step S2). Specifically, while nitrogen is supplied through the gas ring 90 into the chamber 6, the main valve 191 is opened, with the vacuum pump 193 in operation, to exhaust the gas from the chamber 6. At this time, the flow rate of the gas exhausted from the chamber 6 is significantly higher than the flow rate of nitrogen supplied into the chamber 6. This rapidly reduces the pressure in the chamber 6 which in turn decreases to less than atmospheric pressure. The pressure in the chamber 6 is reduced to approximately 5 kPa, for example. Thus, a nitrogen atmosphere with low pressure is formed in the chamber 6.

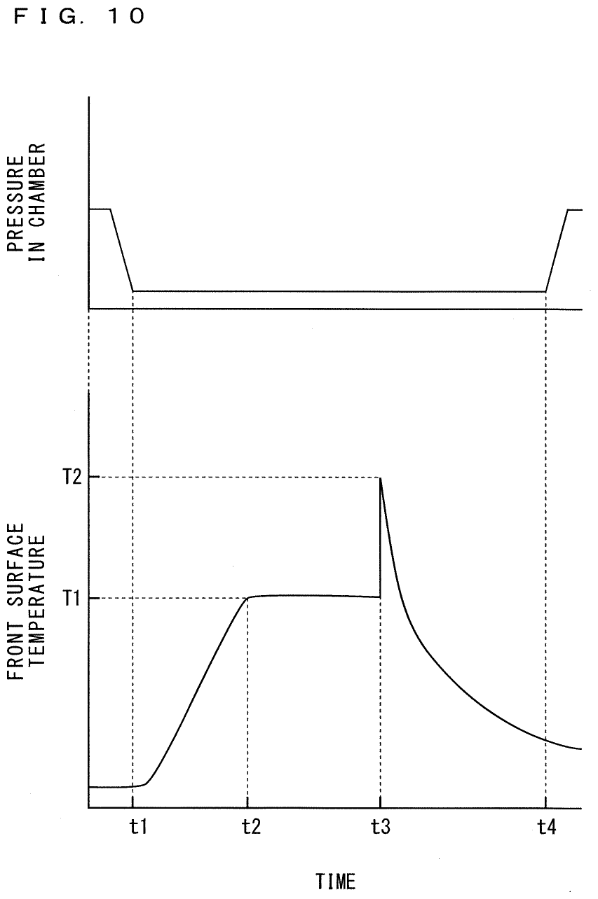

Next, the 40 halogen lamps HL in the halogen heating part 4 turn on simultaneously to start preheating (or assist-heating) (Step S3). FIG. 10 is a graph showing transitions of the pressure in the chamber 6 and the front surface temperature of the semiconductor wafer W. After the pressure in the chamber 6 is reduced to approximately 5 kPa at time t1, the halogen lamps HL turn on to start the preheating of the semiconductor wafer W. Halogen light emitted from the halogen lamps HL is transmitted through the lower chamber window 64 and the susceptor 74 both made of quartz, and impinges upon the lower surface of the semiconductor wafer W. By receiving halogen light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W is measured by the radiation thermometer 20 when the halogen lamps HL perform the preheating. Specifically, the radiation thermometer 20 receives infrared radiation emitted from the lower surface of the semiconductor wafer W held by the susceptor 74 through the opening 78 and passing through the transparent window 21 to measure the temperature of the semiconductor wafer

W which is on the increase. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured by the radiation thermometer 20. The preheating temperature T1 is 800° C., for example.

After the temperature of the semiconductor wafer W reaches the preheating temperature T1, the controller 3 maintains the temperature of the semiconductor wafer W at the preheating temperature T1 for a short time. Specifically, at time t2 when the temperature of the semiconductor wafer W measured by the radiation thermometer 20 reaches the preheating temperature T1, the controller 3 adjusts the output from the halogen lamps HL to maintain the temperature of the semiconductor wafer W at approximately the preheating temperature T1.

By performing such preheating using the halogen lamps HL, the temperature of the entire semiconductor wafer W is uniformly increased to the preheating temperature T1. In the stage of preheating using the halogen lamps HL, the semiconductor wafer W shows a tendency to be lower in temperature in the peripheral portion thereof where heat dissipation is liable to occur than in the central portion thereof. However, the halogen lamps HL in the halogen heating part 4 are disposed at a higher density in the region opposed to the peripheral portion of the semiconductor wafer W than in the region opposed to the central portion thereof. This causes a greater amount of light to impinge upon the peripheral portion of the semiconductor wafer W where heat dissipation is liable to occur, thereby providing a uniform in-plane temperature distribution of the semiconductor wafer W in the stage of preheating. In the step of preheating using the halogen lamps HL, the pressure in the chamber 6 is reduced to less than atmospheric pressure, so that a nitrogen atmosphere with low pressure is formed in the chamber 6. For this reason, an oxidation reaction is suppressed on the front surface of the semiconductor wafer W.

Gas is stored in the gas storage tank 152 (Step S4) in parallel with the reduction in pressure in the chamber 6 and the preheating of the semiconductor wafer W. In other words, Steps S2 and S3 are processes executed in parallel with Step S4. The ozone generator 151 continues to generate ozone at all times, and continues to feed ozone at a constant flow rate to the gas storage tank 152. To achieve the feed of ozone at a constant flow rate from the ozone generator 151 to the gas storage tank 152, a mass flow controller (MFC) may be provided in the pipe between the ozone generator 151 and the gas storage tank 152. The ozone fed from the ozone generator 151 is stored temporarily in the gas storage tank 152.

Except when ozone is supplied to the chamber 6, the supply valve 153 is closed and the exhaust valve 154 is open. Thus, the ozone stored in the gas storage tank 152 continues to be exhausted through the exhaust pipe 155. That is, while newly generated ozone continues to be supplied to the gas storage tank 152, ozone continues to be exhausted from the gas storage tank 152. If the degree of opening of the exhaust valve 154 is set to an appropriate value, ozone will be stored at a constant pressure in the gas storage tank 152. In the present preferred embodiment, ozone is stored in the gas storage tank 152, for example, at a pressure of 0.2 MPa which is higher than atmospheric pressure. That is, the pressure in the gas storage tank 152 is maintained at a pressure higher than atmospheric pressure by the exhaust valve 154. Based on the pressure in the gas storage tank 152 which is measured by the pressure sensor 157, the controller 3 may effect feedback control of the degree of opening of the exhaust valve 154 so that the pressure in the gas storage tank 152 has a constant value higher than atmospheric pressure.

The flash lamps FL in the flash heating part 5 irradiate the front surface of the semiconductor wafer W held by the susceptor 74 with a flash of light at time t3 when a predetermined time period has elapsed since the temperature of the semiconductor wafer

W reached the preheating temperature T1. The flash of light emitted from the flash lamps FL is sequentially transmitted through the lamp light radiation window 53, the upper chamber window 63, and the shower plate 30 which are all made of quartz, and impinges upon the front surface of the semiconductor wafer W to achieve the flash heating of the semiconductor wafer W.

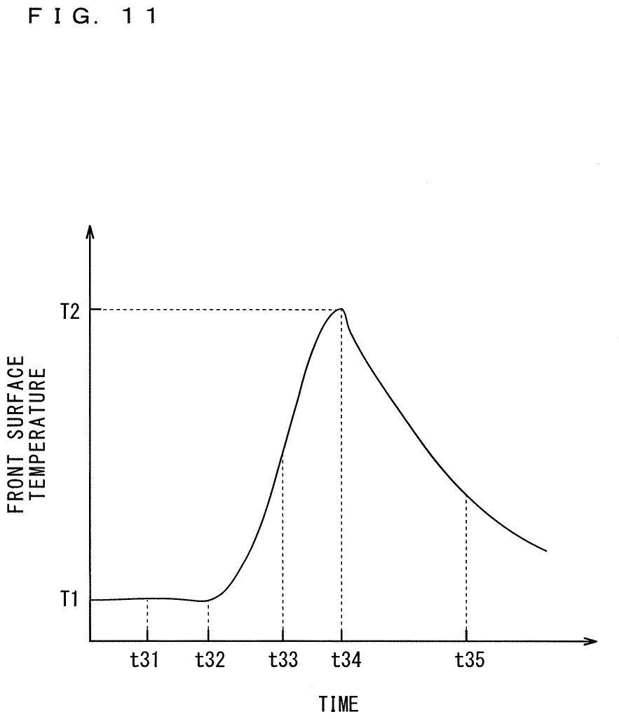

FIG. 11 is a graph showing changes in the front surface temperature of the semiconductor wafer W before and after the flash irradiation. At time t32, the flash lamps FL turn on to start the flash irradiation (Step S5). The flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. Thus, the front surface temperature of the semiconductor wafer W irradiated with the flash of light increases rapidly in a short time to reach a treatment temperature T2 at time t34. The treatment temperature T2 is 1200° C., for example. A time period from the time t32 when the flash irradiation starts to the time t34 when the front surface temperature of the semiconductor wafer W reaches the treatment temperature T2 that is a peak (or a time period for which the temperature is increased by the flash heating) ranges from several milliseconds to tens of milliseconds. It should be noted that the time scale of the abscissa of FIG. 11 is a greatly magnified version of the time scale of the abscissa of FIG. 10. Thus, the times t32 to t34 in FIG. 11 are shown as overlaid on the time t3 in FIG. 10.

The supply valve 153 is opened and the exhaust valve 154 is closed at time t33 between the time t32 when the flash lamps FL turn on to start the flash irradiation and the time t34 when the front surface temperature of the semiconductor wafer W reaches the treatment temperature T2 (Step S6). Specifically, the controller 3 issues a signal for opening the supply valve 153 and closing the exhaust valve 154 at time t31 which is before the time t32 when the flash lamps FL turn on because it takes a certain amount of time (not greater than one second) to perform communication and drive the valves after the controller 3 issues the signal for opening and closing the valves. The time t33 when the signal transmitted by communication causes the supply valve 153 to actually open and causes the exhaust valve 154 to actually close is between the time t32 when the flash irradiation starts and the time t34 when the front surface temperature of the semiconductor wafer W reaches the peak temperature (the treatment temperature T2).

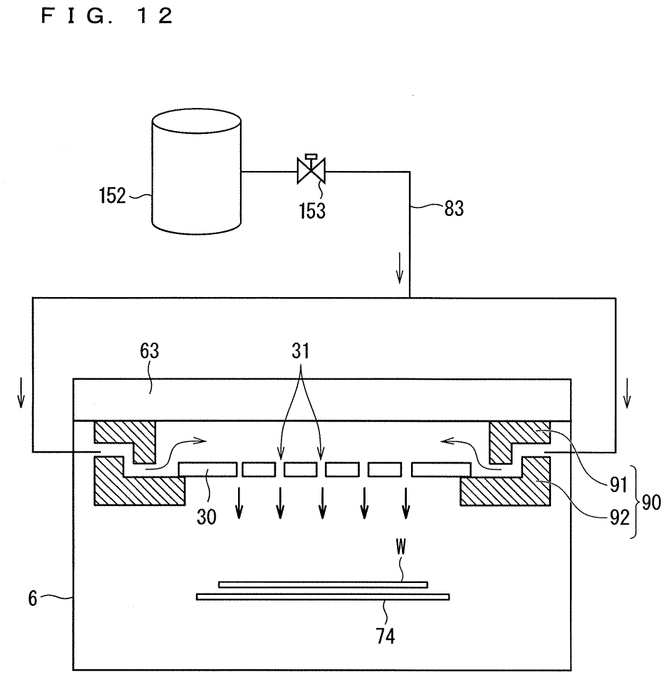

FIG. 12 is a view schematically showing a phenomenon occurring in the chamber 6 at the instant of opening the supply valve 153. At the time t32 when the flash irradiation starts (i.e., immediately before the supply valve 153 is opened), the pressure in the gas storage tank 152 is a pressure (e.g., 0.2 Mpa) higher than atmospheric pressure, and the pressure in the chamber 6 is reduced to a pressure (e.g., 5 kPa) lower than atmospheric pressure. When the supply valve 153 is opened at the time t33 in this state, ozone gas flows all at once from the gas storage tank 152 which is pressurized to higher than atmospheric pressure toward the chamber 6 which is depressurized to lower than atmospheric pressure. As a result, a large amount of ozone gas is instantaneously supplied into the chamber 6. The ozone gas supplied from the gas storage tank 152 passes through the flow passage of the gas ring 90 and flows into the space between the upper chamber window 63 and the shower plate 30. Then, the ozone gas is ejected downwardly through the ejection holes 31, and blown onto the semiconductor wafer W held by the susceptor 74. It should be noted that a substantially constant pressure (5 kPa in the aforementioned example) is maintained in the chamber 6 by means of the automatic pressure control valve 192 even when the ozone gas flows into the chamber 6 instantaneously.

Referring again to FIG. 11, the front surface temperature of the semiconductor wafer W decreases rapidly after reaching the peak temperature at the time t34 because the time period for the flash irradiation is an extremely short time period ranging from 0.1 to 100 milliseconds. The supply valve 153 is closed and the exhaust valve 154 is opened at time t35 which is later than the time t34 when the front surface temperature of the semiconductor wafer W reaches the peak temperature and which is within one second of the time t33 when the supply valve 153 is opened (Step S7). This stops the supply of ozone to the chamber 6. Thus, ozone is supplied to the chamber 6 only between the times t33 and t35 which are before and after the front surface temperature of the semiconductor wafer W reaches the peak temperature by the flash irradiation.

Ozone is supplies only for a time period (a peak temperature region) before and after the front surface temperature of the semiconductor wafer W reaches the peak temperature by the flash irradiation, which in turn causes oxidation to occur in part of the front surface of the semiconductor wafer W where silicon is exposed, thereby forming a silicon oxide film (a thin film of silicon dioxide (SiO₂)). The thickness of the formed silicon oxide film is approximately 10 Å because the time period for which ozone is supplied to around the semiconductor wafer W is as short as one second or less.

After a predetermined time period has elapsed since the front surface temperature of the semiconductor wafer W reached the treatment temperature T2 at the time t34, the halogen lamps HL also turn off. This causes the temperature of the semiconductor wafer W to decrease also from the preheating temperature T1. The radiation thermometer 20 measures the temperature of the semiconductor wafer W which is on the decrease. The result of measurement is transmitted to the controller 3. Even after the supply of ozone to the chamber 6 is stopped at the time t35, the exhaust part 190 continues to exhaust gas from the chamber 6. This exhausts residual ozone from the chamber 6.

After the temperature of the semiconductor wafer W is decreased to a predetermined temperature or below and the ozone within the chamber 6 is sufficiently exhausted, the exhaust of gas from the chamber 6 is stopped and nitrogen is supplied into the chamber 6 at time t4 (FIG. 10), so that the pressure in the chamber 6 is returned to atmospheric pressure. Thereafter, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 to the outside (Step S8). Thus, the heat treatment apparatus 1 completes the heating treatment of the semiconductor wafer W.

In the present preferred embodiment, the controller 3 controls the gas supply part 150 so that the supply valve 153 is opened in such a condition that the pressure in the gas storage tank 152 is higher than atmospheric pressure and the pressure in the chamber 6 is reduced to lower than atmospheric pressure during the flash irradiation. Opening the supply valve 153 when the gas storage tank 152 is pressurized and the chamber 6 is depressurized causes ozone gas to flow all at once from the gas storage tank 152 toward the chamber 6, thereby supplying the ozone gas instantaneously into the chamber 6.

In the present preferred embodiment, the timing of opening the supply valve 153 is between the time when the flash lamps FL turn on to start the flash irradiation and the time when the front surface temperature of the semiconductor wafer W reaches the peak temperature (the treatment temperature T2). In addition, the timing of closing the supply valve 153 is later than the time when the front surface temperature of the semiconductor wafer W reaches the peak temperature and is within one second of opening the supply valve 153. Thus, ozone is supplied only in the peak temperature region which is before and after the front surface temperature of the semiconductor wafer W reaches the peak temperature during the flash irradiation. As a result, ozone is supplied for a short time period of one second or less including the instant at which the front surface temperature of the semiconductor wafer W is the highest to cause the oxidation reaction to proceed, thereby allowing the formation of a good-quality thin silicon oxide film.

While the preferred embodiment according to the present invention has been described hereinabove, various modifications of the present invention in addition to those described above may be made without departing from the scope and spirit of the invention. For example, the supply valve 153 is opened between the time when the flash irradiation starts and the time when the front surface temperature of the semiconductor wafer W reaches the peak temperature in the aforementioned preferred embodiment. The present invention, however, is not limited to this. It is sufficient if the supply valve 153 is open at least when the front surface temperature of the semiconductor wafer W has reached the peak temperature. For example, the supply valve 153 may be opened immediately before the flash irradiation starts.

In the aforementioned preferred embodiment, the supply valve 153 is closed within one second of the time when the supply valve 153 is opened. However, this time interval is preferably as short as possible, and ideally ranges from tens of milliseconds to approximately 100 milliseconds. In consideration of the driving time of the supply valve 153, however, at least 400 milliseconds are required between the opening and closing of the supply valve 153.

In the aforementioned preferred embodiment, ozone is stored in the gas storage tank 152 and supplied to the chamber 6. The present invention, however, is not limited to this. Oxygen (O₂), ammonia (NH₃), nitrogen (N₂), or argon (Ar) may be supplied to the chamber 6 in the same manner as in the aforementioned preferred embodiment. In other words, the treatment gas to be stored in the gas storage tank 152 and supplied to the chamber 6 may be one selected from the group consisting of oxygen, ozone, ammonia, nitrogen, and argon.

Although the 30 flash lamps FL are provided in the flash heating part 5 in the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (e.g., xenon arc lamps) or LED lamps may be used as the continuous lighting lamps to perform the preheating.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for heating a substrate by irradiating the substrate with a flash of light, comprising:
a chamber for receiving a substrate therein;
a flash lamp for irradiating a front surface of said substrate received in said chamber with a flash of light to increase the temperature of the front surface of said substrate to a predetermined treatment temperature;
a gas supply part for supplying a treatment gas into said chamber;
an exhaust part for exhausting gas from said chamber to reduce the pressure in said chamber; and
a controller for controlling said gas supply part and said exhaust part,
wherein said gas supply part includes a gas storage part for storing the treatment gas, and a supply valve provided in a pipe for connecting said gas storage part and said chamber to each other for communication therebetween, and
wherein said controller controls said gas supply part so that said supply valve is opened at a predetermined timing in such a condition that the pressure in said gas storage part is higher than atmospheric pressure and the pressure in said chamber is reduced to lower than atmospheric pressure.

2. The heat treatment apparatus according to claim 1,
wherein said controller controls said gas supply part so that said supply valve is opened between the time when said flash lamp turns on to start flash irradiation and the time when the temperature of the front surface of said substrate reaches said treatment temperature.

3. The heat treatment apparatus according to claim 2,
wherein said controller controls said gas supply part so that said supply valve is closed within one second of the time when said supply valve is opened.

4. The heat treatment apparatus according to claim 1,
wherein said gas supply part further includes an exhaust valve provided in an exhaust pipe from said gas storage part, and
wherein said exhaust valve maintains a pressure higher than atmospheric pressure in said gas storage part.

5. The heat treatment apparatus according to claim 1,
wherein said treatment gas is a gas selected from the group consisting of oxygen, ozone, ammonia, nitrogen, and argon.

6. A method of heating a substrate by irradiating the substrate with a flash of light, comprising the steps of:
(a) receiving a substrate in a chamber;
(b) irradiating a front surface of said substrate received in said chamber with a flash of light from a flash lamp to increase the temperature of the front surface of said substrate to a predetermined treatment temperature;
(c) exhausting gas from said chamber to reduce the pressure in said chamber to lower than atmospheric pressure; and
(d) storing a treatment gas in a gas storage part to make the pressure in said gas storage part higher than atmospheric pressure,
wherein a supply valve provided in a pipe for connecting said gas storage part and said chamber to each other for communication therebetween is opened at a predetermined timing in such a condition that the pressure in said gas storage part is higher than atmospheric pressure and the pressure in said chamber is reduced to lower than atmospheric pressure.

7. The method according to claim 6,
wherein said supply valve is opened between the time when said flash lamp turns on to start flash irradiation and the time when the temperature of the front surface of said substrate reaches said treatment temperature.

8. The method according to claim 7,
wherein said supply valve is closed within one second of the time when said supply valve is opened.

9. The method according to claim 6,
wherein an exhaust valve provided in an exhaust pipe from said gas storage part maintains a pressure higher than atmospheric pressure in said gas storage part.

10. The method according to claim 6,
wherein said treatment gas is a gas selected from the group consisting of oxygen, ozone, ammonia, nitrogen, and argon.
